(19) United States
(12) Patent Application Publication
(10) Pub. No.: US 2026/0143892 A1
(43) Pub. Date: May 21, 2026

(54) PIXEL UNIT AND DISPLAY PANEL

(71) Applicant: AUO Corporation, Hsinchu City (TW)

(72) Inventors: Chia-Ting Hsieh, Hsinchu City (TW); Tzu-Chin Huang, Hsinchu City (TW); Chan-Jui Liu, Hsinchu City (TW)

(73) Assignee: AUO Corporation, Hsinchu City (TW)

(21) Appl. No.: 19/239,990

(22) Filed: Jun. 17, 2025

(30) Foreign Application Priority Data
Nov. 18, 2024 (TW) 113144240

(51) Int. Cl. H10H 29/855

(52) U.S. Cl. CPC H10H 29/855

(57) ABSTRACT

Provided is a display panel, which includes a first substrate, a second substrate and multiple pixel units. Each of the pixel units includes a light emitting element, an optical layer, a microstructure layer and a low refractive index layer. The light emitting element is disposed on an inner surface of the first substrate. The optical layer covers the light emitting element. The microstructure layer is disposed on a top surface of the optical layer away from the inner surface of the first substrate. The low refractive index layer is disposed between the second substrate and the microstructure layer. A refractive index of the low refractive index layer is less than a refractive index of the microstructure layer and a refractive index of the second substrate.

### CROSS-REFERENCE TO RELATED APPLICATION

This application claims the priority benefit of Taiwan application serial no. 113144240, filed on Nov. 18, 2024. The entirety of the above-mentioned patent application is hereby incorporated by reference herein and made a part of this specification.

### BACKGROUND

### Technical Field

The disclosure relates to a pixel unit and a display panel.

### Related Art

A display panel includes multiple layer structures. Light might be reflected between the layer structures before being emitted from the display panel, causing adverse phenomena such as halo effect, which reduces display quality.

### SUMMARY

The disclosure provides a pixel unit and a display panel, which can avoid adverse phenomena such as halo effect, and a light emission efficiency of the display panel is high.

According to an embodiment of the disclosure, a display panel is provided, which includes a first substrate, a second substrate, and multiple pixel units between the first substrate and the second substrate. Each of the pixel units includes a light emitting element, an optical layer, a microstructure layer, and a low refractive index layer. The light emitting element is disposed on an inner surface of the first substrate. The optical layer covers the light emitting element. The microstructure layer is disposed on a top surface of the optical layer away from the inner surface. The low refractive index layer is disposed between the second substrate and the microstructure layer. A refractive index of the low refractive index layer is less than a refractive index of the microstructure layer and a refractive index of the second substrate.

According to an embodiment of the disclosure, a pixel unit is provided, which is adapted to be disposed between a first substrate and a second substrate, and includes a light emitting element, an optical layer, a microstructure layer, and a low refractive index layer. The light emitting element is disposed on an inner surface of the first substrate. The optical layer covers the light emitting element. The microstructure layer is disposed on a top surface of the optical layer away from the inner surface. The low refractive index layer is disposed between the second substrate and the microstructure layer. A refractive index of the low refractive index layer is less than a refractive index of the microstructure layer and a refractive index of the second substrate.

Based on the above, the display panel provided by the embodiment of the disclosure includes the pixel units. The pixel units include the low refractive index layer and the microstructure layer. The low refractive index layer is located between an upper substrate of the display panel and the microstructure layer of the pixel unit. The refractive index of the low refractive index layer is less than the refractive index of the upper substrate and the refractive index of the microstructure layer. Accordingly, a recovery rate of large-angle light, a transmittance of the low refractive index layer, and a transmittance of the upper substrate are improved, improving the forward light extraction of the display panel.

In order to make the features and advantages of the disclosure more comprehensible, the following examples are given and described in detail with the accompanying drawings as follows.

### BRIEF DESCRIPTION OF THE DRAWINGS

FIG. 1, FIG. 2, FIG. 3, FIG. 4A, and FIG. 5A are schematic diagrams of a display panel according to multiple embodiments of the disclosure.

FIG. 4B and FIG. 5B are respectively partially enlarged views of FIG. 4A and FIG. 5A.

### DESCRIPTION OF THE EMBODIMENTS

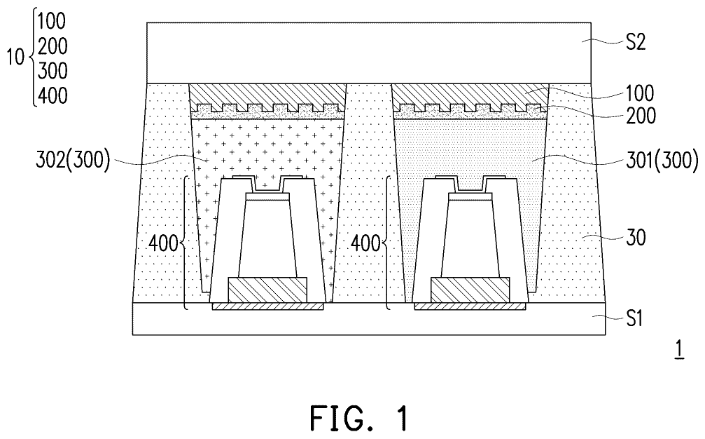

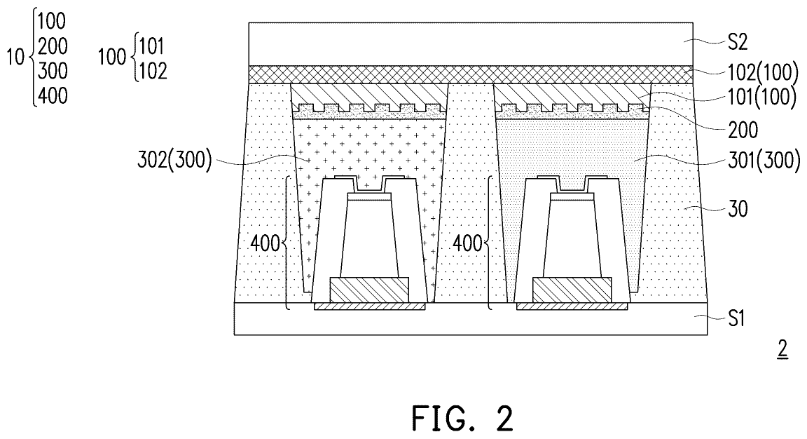

Refer to FIG. 1, which is a schematic diagram of a display panel according to an embodiment of the disclosure.

A display panel 1 includes a first substrate S1, a second substrate S2, and multiple pixel units 10 and multiple bank structures 30 between the first substrate S1 and the second substrate S2. The bank structures 30 are respectively disposed between the adjacent pixel units 10. Each of the pixel units 10 includes a light emitting element 400, an optical layer 300, a microstructure layer 200, and a low refractive index layer 100.

The light emitting element 400 is disposed on an inner surface of the first substrate S1 facing the second substrate S2, and is, for example, an electroluminescent device, such as a light-emitting diode and an organic light-emitting diode. However, the disclosure is not limited thereto. The optical layer 300 covers the light emitting element 400, and may be, for example, a transparent layer 301 (or a scattering layer 301) and a color conversion layer 302. The microstructure layer 200 is disposed on a top surface of the optical layer 300, and includes multiple microstructures protruding in a direction away from the optical layer 300. A distance between a top surface of the microstructure layer 200 and the first substrate S1 is less than a distance between a top surface of the corresponding bank structure 30 and the first substrate S1. The low refractive index layer 100 is disposed between the second substrate S2 and the microstructure layer 200.

It should be specifically noted that a refractive index of the low refractive index layer 100 is configured to be less than a refractive index of the microstructure layer 200, and less than a refractive index of the second substrate S2. Since the refractive index of the low refractive index layer 100 is less than the refractive index of the microstructure layer 200, and the top surface of the microstructure layer 200 is lower than the top surface of the corresponding bank structure 30, for certain light emitted by the light emitting element 400, if total reflection occurs at an interface between the microstructure layer 200 and the low refractive index layer 100, the light may be reflected back to the optical layer 300 until penetrating the interface between the microstructure layer 200 and the low refractive index layer 100 at an angle less than a total reflection angle. In addition, since all the light transmitting the interface between the microstructure layer 200 and the low refractive index layer 100 is incident on the low refractive index layer 100 at an angle less than the total reflection angle of the interface, and the refractive index of the low refractive index layer 100 is less than the refractive index of the second substrate S2, total reflection may not occur at an interface between the low refractive index layer 100 and the second substrate S2. Accordingly, optical loss may be avoided, improving the current efficiency of the display panel 1.

The second substrate S2 is an upper substrate of the display panel 1. In some preferred embodiments, the refractive index of the low refractive index layer 100 is configured to fall within a range of 1.0 to 1.2, or within a range of 1.0 to 1.1. In some embodiments, the low refractive index layer 100 may be, for example, a vacuum layer and a medium layer. The medium layer may include, for example, an air layer. Since the refractive index of the low refractive index layer 100 is close to a refractive index of the air above the second substrate S2 (approximately 1.0), light entering the second substrate S2 may all transmit a top surface of the second substrate S2 away from the first substrate S1, and total reflection may not occur on the top surface of the second substrate S2, which may avoid optical loss, further improving the current efficiency of the display panel 1.

To fully describe various implementation aspects of the disclosure, other embodiments of the disclosure are described in the following. It must be noted here that the following embodiments use the reference numerals and part of the contents of the foregoing embodiments. The same numerals are used to denote the same or similar elements, and the description of the same technical content is omitted. For the description of the omitted parts, reference may be made to the foregoing embodiments, and thus the description is not repeated in the following embodiments.

Refer to FIG. 2, which is a schematic diagram of a display panel according to an embodiment of the disclosure.

A display panel 2 of the embodiment has substantially a same structure as the display panel 1. The difference between the display panel 2 and the display panel 1 is that the low refractive index layer 100 includes a first low refractive index layer 101 and a second low refractive index layer 102. The first low refractive index layer 101 is disposed between the microstructure layer 200 and the second low refractive index layer 102. A refractive index of the first low refractive index layer 101 is less than a refractive index of the second low refractive index layer 102.

In detail, the refractive indices of the first low refractive index layer 101 and the second low refractive index layer 102 are both less than the refractive index of the microstructure layer 200 and the refractive index of the second substrate S2. For example, in some embodiments, the refractive index of the microstructure layer 200 and the refractive index of the second substrate S2 are approximately 1.5, the refractive index of the first low refractive index layer 101 falls within a range of 1.0 to 1.2, and the refractive index of the second low refractive index layer falls within a range of 1.2 to 1.4.

Since the refractive index of the first low refractive index layer 101 is less than the refractive index of the microstructure layer 200, and a top surface of the microstructure layer 200 is lower than a top surface of the corresponding bank structure 30, for certain light emitted from the light-emitting element 400, if total reflection occurs at an interface between the microstructure layer 200 and the first low refractive index layer 101, the light may be reflected back to the optical layer 300 until penetrating the interface between the microstructure layer 200 and the first low refractive index layer 101 at an angle less than a total reflection angle. In addition, since all the light transmitting the interface between the microstructure layer 200 and the first low refractive index layer 101 is incident on the first low refractive index layer 101 at an angle less than the total reflection angle of the interface, the refractive index of the first low refractive index layer 101 is less than the refractive index of the second low refractive index layer 102, and the refractive index of the second low refractive index layer 102 is less than the refractive index of the second substrate S2, total reflection may not occur at an interface between the first low refractive index layer 101 and the second low refractive index layer 102 and an interface between the second low refractive index layer 102 and the second substrate S2. Accordingly, optical loss can be avoided, improving the current efficiency of the display panel 2.

In addition, since the refractive index of the first low refractive index layer 101, the refractive index of the second low refractive index layer 102, and the refractive index of the second substrate S2 gradually increase, the reflectivity at the interfaces between these layers or elements may be decreased, which improves transmittance, avoids optical loss, and improves the current efficiency of the display panel 2.

Refer to FIG. 3, which is a schematic diagram of a display panel according to an embodiment of the disclosure. A display panel 3 of the embodiment has substantially the same structure as the display panel 1, which will not be elaborated here. In the display panel 3, the microstructure layer 200 includes a curved surface protruding in a direction away from the optical layer 300, thereby reducing a probability of total reflection occurring at an interface between the microstructure layer 200 and the low refractive index layer 100, improving the current efficiency of the display panel 3.

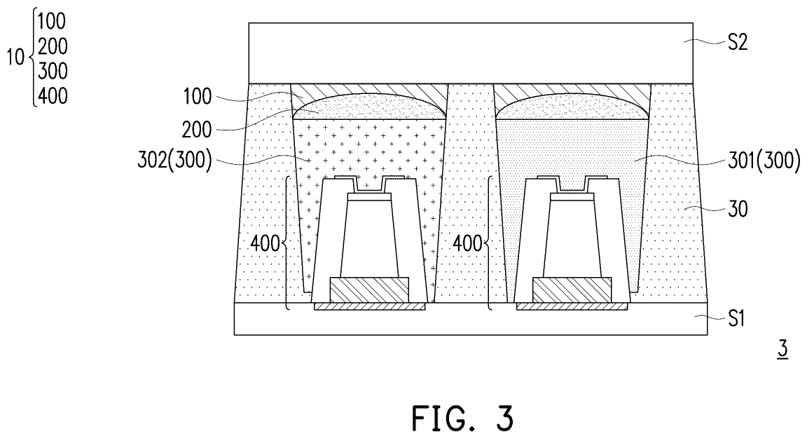

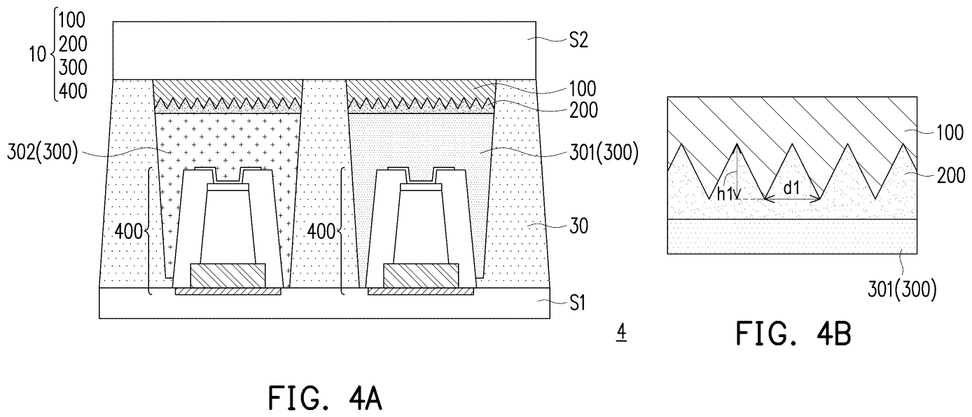

Referring to FIG. 4A and FIG. 4B, FIG. 4A is a schematic diagram of a display panel according to an embodiment of the disclosure, and FIG. 4B is a partially enlarged view of FIG. 4A. A display panel 4 of the embodiment has substantially the same structure as the display panel 1, which will not be elaborated here. The difference between the display panel 4 and the display panel 1 is that, in the display panel 1, the microstructure layer 200 includes multiple micro-column structures protruding in a direction away from the optical layer 300; in the display panel 4, the microstructure layer 200 includes multiple micro-prism structures protruding in a direction away from the optical layer 300. Accordingly, a probability of total reflection occurring at an interface between the microstructure layer 200 and the low refractive index layer 100 may be reduced, improving the current efficiency of the display panel 1 and the display panel 4. In addition, referring to FIG. 4B, in a preferred embodiment, a height h1 of each of the micro-prism structures in the direction away from the optical layer 300 is configured to be greater than or equal to a width d1, thereby increasing a slope of a side of the micro-prism structures, further reducing the probability of total reflection, and improving the current efficiency of the display panel 4.

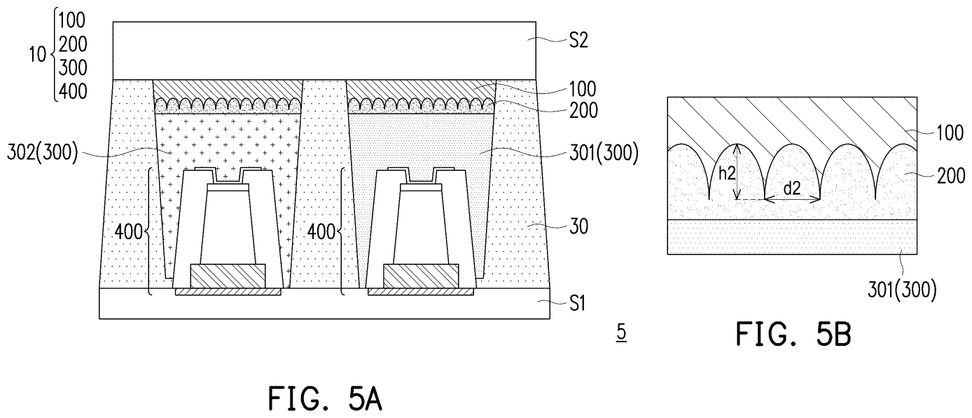

Referring to FIG. 5A and FIG. 5B, FIG. 5A is a schematic diagram of a display panel according to an embodiment of the disclosure, and FIG. 5B is a partially enlarged view of FIG. 5A. A display panel 5 of the embodiment has substantially the same structure as the display panel 1, which will not be elaborated here. In the display panel 5, the microstructure layer 200 includes multiple micro-lens structures protruding in a direction away from the optical layer 300. Accordingly, a probability of total reflection occurring at an interface between the microstructure layer 200 and the low refractive index layer 100 may be reduced, improving the current efficiency of the display panel 5. In addition, referring to FIG. 5B, in a preferred embodiment, a height h2 of each of the micro-lens structures in the direction away from the optical layer 300 is configured to be greater than or equal to a width d2, thereby further reducing the probability of total reflection, and improving the current efficiency of the display panel 5.

It should be noted that, compared to a comparative example without disposing the low refractive index layer 100 between the microstructure layer 200 and the second substrate S2, the display panel 5 provided in the embodiment utilizes a refractive index difference between the microstructure layer 200 and the low refractive index layer 100 to improve a recovery rate of large-angle light, as well as a transmittance of the low refractive index layer 100 and a transmittance of the second substrate S2, thereby obtaining a 26.2% gain in forward light extraction. Furthermore, compared to another comparative example provided with the low refractive index layer 100 but without the microstructure layer 200, the display panel 5 provided in the embodiment also obtains a 13.3% gain in forward light extraction.

In summary, the display panel provided by the embodiment of the disclosure is provided with the low refractive index layer and the microstructure layer. The low refractive index layer is located between the upper substrate and the microstructure layer. The refractive index of the low refractive index layer is less than the refractive index of the upper substrate and the refractive index of the microstructure layer. Accordingly, the recovery rate of large-angle light, the transmittance of the low refractive index layer, and the transmittance of the upper substrate are improved, improving the forward light extraction of the display panel.

What is claimed is:

1. A display panel, comprising a first substrate, a second substrate and a plurality of pixel units between the first substrate and the second substrate, and each of the pixel units comprising:
a light emitting element, disposed on an inner surface of the first substrate;
an optical layer, covering the light emitting element;
a microstructure layer, disposed on a top surface of the optical layer away from the inner surface; and
a low refractive index layer, disposed between the second substrate and the microstructure layer,
wherein a refractive index of the low refractive index layer is less than a refractive index of the microstructure layer and a refractive index of the second substrate.

2. The display panel according to claim 1, further comprising a plurality of bank structures, respectively disposed between the adjacent plurality of pixel units, and a distance between a top surface of the microstructure layer of each of the pixel units and the first substrate is less than a distance between a top surface of the plurality of bank structures and the first substrate.

3. The display panel according to claim 1, wherein the refractive index of the low refractive index layer falls within a range of 1.0 to 1.2.

4. The display panel according to claim 3, wherein the low refractive index layer directly contacts the second substrate and the microstructure layer.

5. The display panel according to claim 3, wherein the low refractive index layer is a vacuum layer or an air layer.

6. The display panel according to claim 1, wherein the low refractive index layer comprises a first low refractive index layer and a second low refractive index layer, the first low refractive index layer is disposed between the microstructure layer and the second low refractive index layer, and a refractive index of the first low refractive index layer is less than a refractive index of the second low refractive index layer.

7. The display panel according to claim 6, wherein the refractive index of the second low refractive index layer falls within a range of 1.2 to 1.4.

8. The display panel according to claim 7, wherein the refractive index of the first low refractive index layer falls within a range of 1.0 to 1.2.

9. The display panel according to claim 6, wherein the first low refractive index layer directly contacts the microstructure layer, and the second low refractive index layer directly contacts the second substrate.

10. The display panel according to claim 6, wherein the refractive index of the first low refractive index layer, the refractive index of the second low refractive index layer, and the refractive index of the second substrate gradually increase.

11. The display panel according to claim 1, wherein the microstructure layer comprises at least one protruding portion protruding in a direction away from the optical layer, and a height of the at least one protruding portion is greater than or equal to a width of the at least one protruding portion.

12. A pixel unit, adapted to be disposed between a first substrate and a second substrate, and comprising:
a light emitting element, disposed on an inner surface of the first substrate;
an optical layer, covering the light emitting element;
a microstructure layer, disposed on a top surface of the optical layer away from the inner surface; and
a low refractive index layer, disposed between the second substrate and the microstructure layer,
wherein a refractive index of the low refractive index layer is less than a refractive index of the microstructure layer and a refractive index of the second substrate.

13. The pixel unit according to claim 12, wherein the refractive index of the low refractive index layer falls within a range of 1.0 to 1.2.

14. The pixel unit according to claim 13, wherein the low refractive index layer is a vacuum layer or an air layer.

15. The pixel unit according to claim 12, wherein the low refractive index layer comprises a first low refractive index layer and a second low refractive index layer, the first low refractive index layer is disposed between the microstructure layer and the second low refractive index layer, and a refractive index of the first low refractive index layer is less than a refractive index of the second low refractive index layer.

16. The pixel unit according to claim 15, wherein the refractive index of the second low refractive index layer falls within a range of 1.2 to 1.4.

17. The pixel unit according to claim 16, wherein the refractive index of the first low refractive index layer falls within a range of 1.0 to 1.2.

18. The pixel unit according to claim 12, wherein the microstructure layer comprises at least one protruding portion protruding in a direction away from the optical layer, and a height of the at least one protruding portion is greater than or equal to a width of the at least one protruding portion.
